(19) United States
(12) Patent Application Publication
(10) Pub. No.: US 2013/0209200 A1
(43) Pub. Date: Aug. 15, 2013

(54) CARRIER DEVICE

(71) Applicant: KABUSHIKI KAISHA YASKAWA DENKI, (US)

(72) Inventors: Masatoshi FURUICHI, Kitakyushu-shi (JP); Kazunori HINO, Kitakyushu-shi (JP); Daisuke SHIN, Kitakyushu-shi (JP)

(73) Assignee: KABUSHIKI KAISHA YASKAWA DENKI, Kitakyushu-shi (JP)

(21) Appl. No.: 13/726,614

(22) Filed: Dec. 26, 2012

(30) Foreign Application Priority Data
Feb. 14, 2012 (JP) 2012-029801

(51) Int. Cl. H01L 21/677

(52) U.S. Cl. CPC H01L 21/67739
USPC 414/222.07

(57) ABSTRACT

A carrier device according to an aspect of an embodiment includes a carrier chamber, a robot that is placed near one longitudinal-side wall in the carrier chamber, and a linear moving mechanism that has a track by which the robot is linearly moved in the longitudinal direction of the carrier chamber. The arm of the robot is defined to a length by which the arm does not interfere with the other longitudinal-side wall even if the arm is rotated around an arm spindle. The track of the linear moving mechanism has a length by which the leading end of the hand perpendicular to the track reaches a predetermined position in a connecting hole located at an end among connecting holes provided in the longitudinal-side wall.

### CROSS-REFERENCE TO RELATED APPLICATION

This application is based upon and claims the benefit of priority of the prior Japanese Patent Application No. 2012-029801, filed on Feb. 14, 2012, the entire contents of which are incorporated herein by reference.

### FIELD

The embodiment discussed herein is directed to a carrier device.

### BACKGROUND

There is known a conventional carrier device that places a multi-joint robot, which carries a board for a semiconductor wafer or a liquid crystal panel, in a carrier chamber called EFEM (Equipment Front End Module).

The carrier chamber of the conventional carrier device substantially has a shape of a rectangular solid by being surrounded by walls. The longitudinal-side wall that constitutes a part of a peripheral wall is provided with a plurality of connecting holes that are communicated with the outside. A storage vessel and a process chamber of the board are communicated with each other via the connecting holes.

The multi-joint robot placed in the carrier chamber is generally provided close to a one side-wall of the carrier chamber. Herein, a general multi-joint robot includes an arm part that includes a first arm whose bottom end is connected on a base via a first spindle and a second arm whose bottom end is connected to the leading end of the first arm via a second spindle and leading end is provided with a hand. The multi-joint robot drives the plurality of arms and the hand of the arm part to make the hand access a storage vessel and a process chamber.

The conventional technology has been known as disclosed in, for example, Japanese Laid-open Patent Publication No. 2008-28134.

However, when a board is carried out or carried in to a desired storage vessel or process chamber, the conventional carrier device should make the multi-joint robot perform extremely complicated motions while interlocking the first arm, the second arm, and the hand of the multi-joint robot with each other. Therefore, there is a possibility that an access speed to the storage vessel or the process chamber of the hand is decreased. Furthermore, there is a possibility that the precision of an access position of the hand is decreased along with the complicated motions.

### SUMMARY

A carrier device according to an aspect of an embodiment includes a carrier chamber that has a board carrying space, a robot that is placed near a one longitudinal-side wall in the carrier chamber, and a linear moving mechanism that has a track along which the robot is linearly moved in a longitudinal direction of the carrier chamber. The board carrying space of the carrier chamber is formed of a substantially rectangular solid surrounded by walls and is provided with a plurality of connecting holes that are provided side-by-side in longitudinal-side walls of peripheral walls to be communicated with an outside. The bottom end of the robot is provided on a base to be rotatable horizontally via an arm spindle and the leading end is provided with an single arm on which a hand that holds a board to be carried in and out via the connecting hole is provided to be rotatable horizontally. The arm of the robot is defined to a length by which the arm does not interfere with the other-side longitudinal-side wall even if the arm is rotated around the arm spindle. Furthermore, the track of the linear moving mechanism has a length by which a leading end of the hand perpendicular to the track reaches a predetermined position in the connecting hole located at an end among the plurality of connecting holes.

### BRIEF DESCRIPTION OF DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic plan view illustrating a carrier device according to an embodiment;

FIG. 2 is a schematic side view of the carrier device;

FIG. 3 is a block diagram of the carrier device;

FIG. 4 is a schematic explanation diagram illustrating an example of carrying operations of the carrier device;

FIG. 5 is a schematic explanation diagram illustrating an example of carrying operations of the carrier device;

FIG. 6A is a schematic plan view illustrating the carrier device according to a first alternative example;

FIG. 6B is a schematic plan view illustrating the carrier device according to a second alternative example; and

FIG. 6C is a schematic plan view illustrating the carrier device according to a third alternative example.

### DESCRIPTION OF EMBODIMENT

Hereinafter, a carrier device according to an embodiment of the present disclosure will be explained in detail with reference to the accompanying drawings. In addition, the embodiment disclosed below is not intended to limit the present invention.

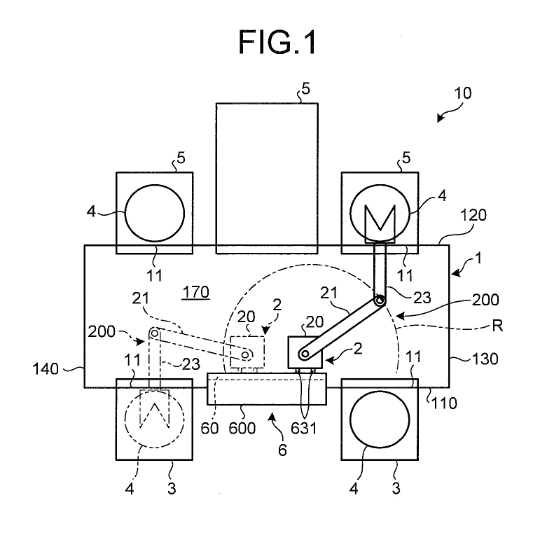

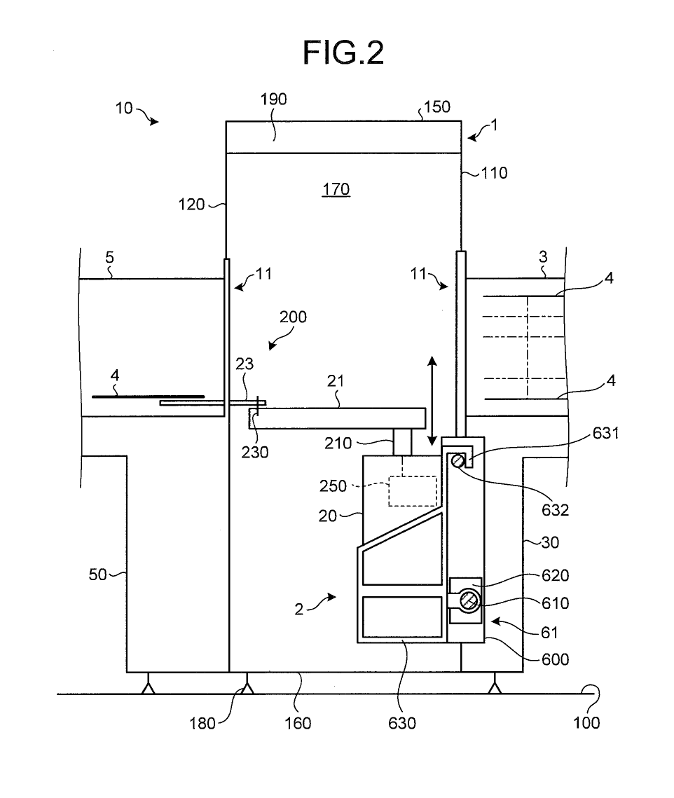

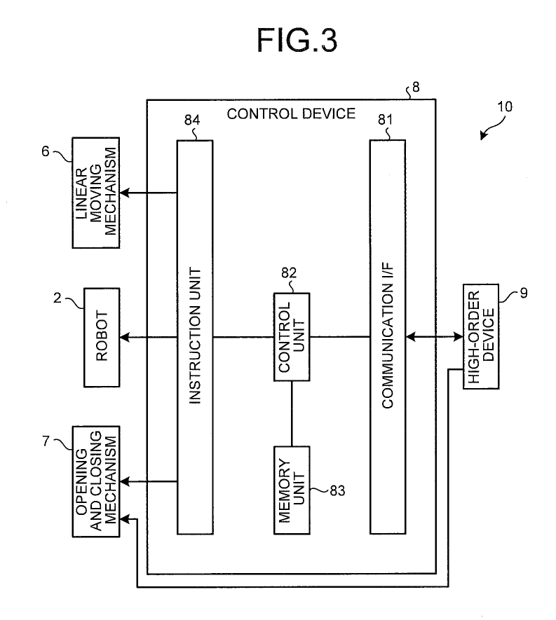

First, the brief of a carrier device 10 according to an embodiment will be explained with reference to FIGS. 1 to 3. FIG. 1 is a schematic plan view illustrating the carrier device 10 according to the present embodiment. FIG. 2 is a schematic side view of the carrier device 10. FIG. 3 is a block diagram of the carrier device 10.

As illustrated in FIGS. 1 and 2, the carrier device 10 includes a carrier chamber 1 that is provided with a plurality of connecting holes 11 that are communicated with the outside and a horizontal carry robot 2 that is placed in the carrier chamber 1 and can carry a board 4 for a semiconductor wafer or a liquid crystal panel.

The carrier chamber 1 is generally a local clean room called EFEM (Equipment Front End Module) and has a substantially rectangular-solid board carrying space 170 surrounded by walls. The walls consist of a first longitudinal-side wall 110, a second longitudinal-side wall 120, a first short-side wall 130, a second short-side wall 140, a ceiling wall 150, and a floor wall 160. Herein, the first longitudinal-side wall 110, the second longitudinal-side wall 120, the first short-side wall 130, and the second short-side wall 140 may be referred to as peripheral walls. Furthermore, the lower surface of the floor wall 160 is provided with legs 180 that support the carrier chamber 1 on an installation surface 100.

The carrier chamber 1 provides a filter unit 190, which stores therein a filter for purifying gas, inside the ceiling wall 150. The carrier chamber 1 is purified by the filter unit 190 and cleans its inside by using a dropping purified air current, in a state where the carrier chamber is blocked from the outside.

The plurality of connecting holes 11 are provided, on a line, in the first and second longitudinal-side walls 110 and 120 that constitute a part of the peripheral walls of the carrier chamber 1.

In the present embodiment, storage vessels 3, which are called FOUP (Front-Opening Unified Pod) and can store therein the board 4 such as wafers in a multistage manner, are attached to the two connecting holes 11 that are formed in the first longitudinal-side wall 110 at predetermined intervals.

Furthermore, process chambers 5, which perform predetermined processes such as CVD (Chemical Vapor Deposition), exposure, etching, and asking on the board 4, are attached to the three connecting holes 11 formed in the second longitudinal-side wall 120.

Meanwhile, the storage vessels 3 and the process chambers 5 are attached to the connecting holes 11 via opening and closing members such as shutters (not illustrated). An opening and closing mechanism 7 (see FIG. 3) that drives the opening and closing members is provided in a storage vessel table 30 that holds the storage vessels 3 and a process chamber table 50 that holds the process chambers 5.

In the carrier device 10 according to the present embodiment, the central process chamber 5 is a large-sized chamber compared to the both-side process chambers 5. However, the size or shape of the process chambers 5 can be set appropriately. Furthermore, it is only sufficient that the shape and configuration of the storage vessels 3 called FOUP and the carrier chamber 1 that connects these vessels have a structure based on a SEMI (Semiconductor Equipment and Materials International) standard.

The robot 2 according to the present embodiment is placed near the first longitudinal-side wall 110 and includes a single arm 21 that is provided with a hand 23 that holds the board 4 that is carried in and out via the connecting hole 11.

The bottom end of the arm 21 is provided on a base 20 via an arm spindle 210 to be rotatable horizontally and the leading end is provided with the hand 23 to be rotatable horizontally via a hand spindle 230 (hereinafter, “horizontal rotation” may be expressed as “turning”). Moreover, the hand 23 can have a configuration that the hand can place thereon and carry the board 4 by its fork-shaped leading end, a configuration that the hand can adsorb the board 4, or a configuration that the hand can grip the board 4.

The arm spindle 210 and the hand spindle 230 are connected to a turning mechanism (not illustrated) that includes a motor, a speed reducer, and the like.

The pillar-shaped arm spindle 210 that supports the arm 21 is attached to the base 20 to be freely lifted and lowered by a lifting and lowering mechanism 250 stored in the base 20.

Furthermore, the carrier device 10 includes a linear moving mechanism 6 that has a track 60 along which the robot 2 is linearly moved in a longitudinal direction of the carrier chamber 1.

As illustrated in FIGS. 1 and 2, the linear moving mechanism 6 is placed in the substantially center of the first longitudinal-side wall 110 of the carrier chamber 1 to be sandwiched by the left and right storage vessels 3.

In other words, the linear moving mechanism 6 includes a case 600, which is placed to be located between the left and right storage vessels 3, in the substantial center of the first longitudinal-side wall 110. A ball screw mechanism 61 that acts as a linear actuator is placed in the case 600. Furthermore, the track 60 that has a slit that is communicated with the board carrying space 170 and the case 600 is formed on a side of the case 600 facing the board carrying space 170 of the carrier chamber 1.

As illustrated in FIG. 2, the ball screw mechanism 61 includes a ball screw shaft 610 that extends in a longitudinal direction under the case 600 and a driving motor 620 that is coupled to one end of the ball screw shaft 610. Moreover, a linear motor can be employed in place of the ball screw mechanism.

Furthermore, the linear moving mechanism 6 according to the present embodiment includes a storage frame 630 that can store therein the robot 2 and moves along the track 60. As illustrated in FIG. 2, the robot 2 can move in the state where the robot is stored in the storage frame 630.

A guide shaft 632 that extends in a longitudinal direction is placed in the case 600. On the other hand, as illustrated in FIG. 2, a guide arm 631 that engages with the guide shaft 632 to slide is provided in the back of the storage frame 630. The guide arm 631 extends from the track 60 formed on the top of the case 600 into the case 600 and further its leading end is folded downward. The folded part and the guide shaft 632 are engaged with each other.

Therefore, upon driving the driving motor 620 of the linear moving mechanism 6, the robot 2 linearly moves smoothly and stably along with the base 20 via the storage frame 630 in a longitudinal direction of the carrier chamber 1.

Furthermore, as illustrated in FIG. 3, the carrier device 10 according to the present embodiment includes a control device 8 that performs operation control of the robot 2, which includes rotation operations of the arm 21 and the hand 23, and operation control of the linear moving mechanism 6.

As illustrated in FIG. 3, the control device 8 includes a communication I/F (interface) 81, a control unit 82, a memory unit 83, and an instruction unit 84.

Each drive system of the robot 2, the linear moving mechanism 6, which includes the linear actuator that linearly moves the robot 2, and the opening and closing mechanism 7, which drives the opening and closing member of the storage vessel 3 and the process chamber 5, are connected to the control device 8. Furthermore, a high-order device 9 to be described below is connected to the control device 8 via the communication I/F 81.

Herein, the communication I/F 81 is a device that performs transmission and reception of communication data between the control device 8 and the high-order device 9. For example, in order to update various types of programs stored in the memory unit 83, the communication I/F 81 can receive appropriate data from the high-order device 9.

The memory unit 83 is a device such as RAM (Random Access Memory), ROM (Read Only Memory), and a hard disk. The memory unit 83 stores drive programs of the robot 2, the linear moving mechanism 6, and the opening and closing mechanism 7.

The control unit 82 includes an arithmetic unit such as a central processing unit (CPU). The control unit 82 outputs driving signals to the robot 2, the linear moving mechanism 6, and the opening and closing mechanism 7 via the instruction unit 84 in accordance with the drive programs stored in the memory unit 83. Generally, a driving signal for the opening and closing mechanism 7 is output from the high-order device 9.

Furthermore, the control unit 82 computes the positions of predetermined base points of the robot 2 on the base 20 and an arm part 200 and performs a computation process of a moving distance of the hand 23 up to the storage vessel 3 and the process chamber 5 on the basis of the base points.

In the robot 2 according to the present embodiment, centers of the arm spindle 210 and the hand spindle 230 and a center of the board 4 placed on the hand 23 are used as the base points of the arm part 200. An undersurface center of the base 20 is used as the base point of the base 20.

As described above, the control unit 82 computes and manages position information of the robot 2 in order to control the motions of the robot 2.

Then, the control unit 82 controls the linear moving mechanism 6, the arm part 200, and the lifting and lowering mechanism 250 on the basis of the computation result. For example, the control unit 82 makes the robot 2 move to an appropriate position of the carrier chamber 1 in its longitudinal direction while driving both or one of “the lifting and lowering mechanism 250” and “the arm 21 and the hand 23” if needed, in such a manner that the board 4 can be carried up to a desired position in the shortest time. In this way, the robot 2 can appropriately lift or lower and turn the arm 21 to put the board 4 in and out via the connecting hole 11 and to carry the held board 4 at a desired position.

In other words, the control device 8 of the carrier device 10 according to the present embodiment can synchronously activate the linear moving mechanism 6 for only a simple straight action and the single arm 21 and the hand 23 of the robot 2 to make the hand 23 access a desired position.

As described above, the carrier device 10 according to the present embodiment does not require complicated control for moving two or more arms of a robot of the conventional carrier device and thus only performs a combination of simple operation controls. Therefore, it is possible to improve an access speed of the hand 23 to the storage vessel 3 and the process chamber 5. Furthermore, it is possible to improve the precision of an access position of the hand 23.

The carrier device 10 according to the present embodiment further has the following configuration in addition to the configuration described above.

In other words, even if the single arm 21 of the robot 2 rotates around the arm spindle 210, the length of the arm 21 is defined so that its leading end does not interfere with the second longitudinal-side wall 120. In other words, as illustrated in FIG. 1, a turning trajectory R of the arm 21 does not contact the second longitudinal-side wall 120 and the process chamber 5.

Therefore, if the hand 23 has a posture in which the hand does not protrude from the leading end of the arm 21, the control device 8 can drive the linear moving mechanism 6 any time and can move the robot 2 at a desired position between both ends of the track 60 at high speed.

In other words, because a linear movement by the linear moving mechanism 6 does not require complicated control, the robot can move at high speed. Moreover, because the control device 8 according to the present embodiment synchronously activates the linear moving mechanism 6 and “the arm 21 and the hand 23” of the robot 2, the control device 8 can make the hand 23 access the desired storage vessel 3 or process chamber 5 in the shortest time.

The track 60 of the linear moving mechanism 6 is defined to a minimum necessary length for the leading end of the hand 23 perpendicular to the track 60 to reach a predetermined position in the connecting hole 11 located at an end among the plurality of connecting holes 11. In other words, the track 60 is defined to a minimum necessary length for the board 4 held in the hand 23 to reach a predetermined position in the connecting hole 11 located at the end among the plurality of connecting holes 11.

In other words, the length of the track 60 is considerably short compared to the first and second longitudinal-side walls 110 and 120 of the carrier chamber 1. However, even if the robot 2 does not directly face the storage vessel 3 or the process chamber 5 connected via the connecting hole 11, particularly the storage vessel 3 or the process chamber 5 located at the end, the leading end of the hand 23 connected to the diagonal arm 21 can arrive at a predetermined position in the connecting hole 11 in a posture perpendicular to the track 60.

In this way, because the length of the track 60 can be reduced as far as possible, a space for installing any device such as a robot controller can be provided near both corners of the first longitudinal-side wall 110 of the carrier chamber 1, for example. Therefore, according to the carrier device 10 of the present embodiment, the inside of the carrier chamber 1 can be effectively used.

Moreover, the length of the track 60 can make the hand 23 access the storage vessel 3 and the process chamber 5 located at the end in a posture in which the hand directly faces them and also can make the hand 23 access the storage vessel 3 and the process chamber 5 close to the arm spindle 210 of the robot 2. In other words, in such a manner that the hand 23 can smoothly access the storage vessel 3 and the process chamber 5 close to the arm spindle 210, the enough length for the robot 2 to keep away from the storage vessel 3 and the process chamber 5 is considered and defined.

Furthermore, in the carrier device 10 according to the present embodiment, the track 60 of the linear moving mechanism 6 is not provided on the floor wall 160 of the carrier chamber 1 but is provided on the peripheral wall. Therefore, there is not a possibility that a bad influence is given to a flow of cleaned air dropping from the filter unit 190. However, it is not prohibited to provide the track 60 of the linear moving mechanism 6 on the floor wall 160 of the carrier chamber 1.

Herein, a board carrying operation of the carrier device 10 according to the present embodiment is specifically explained. A control process of the carrying operation is performed in accordance with the previously-described drive program.

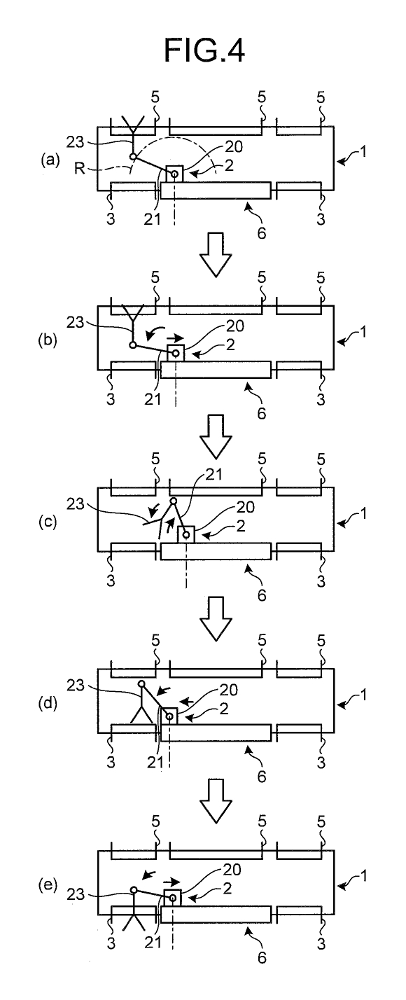

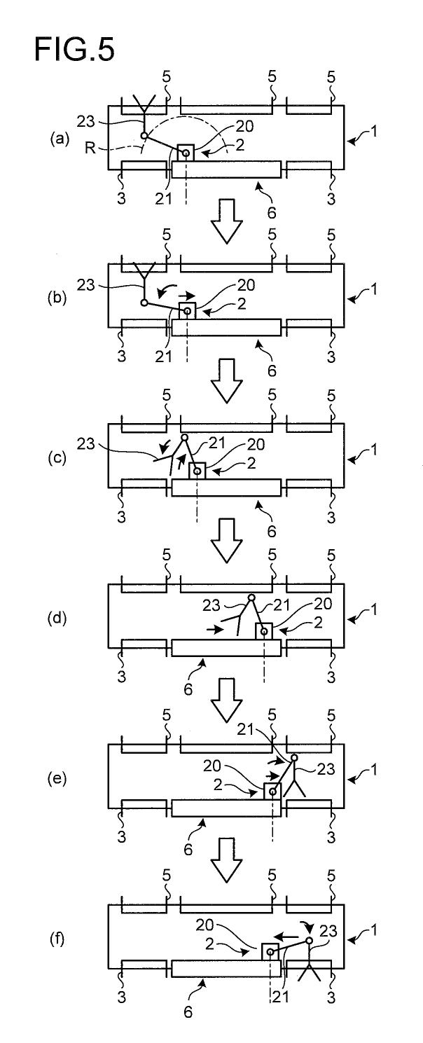

FIGS. 4 and 5 are schematic explanation diagrams illustrating an example of carrying operations of the carrier device 10. First, a carrying operation by which the hand 23 located in the process chamber 5 at the left side of the drawing in the second longitudinal-side wall 120, for example, accesses the left-side storage vessel 3 facing the process chamber will be explained with reference to FIG. 4.

In FIGS. 4 and 5, for the sake of convenience, the board 4 is not illustrated and the reference numbers for detailed components are omitted.

The state of (a) of FIG. 4 is a state where the board 4 on which a predetermined process is terminated is held by the robot 2. As illustrated in (a) of FIG. 4, the robot 2 of the carrier device 10 according to the present embodiment is located at one end (the left end of FIG. 4) of the track 60 (see FIG. 1) of the linear moving mechanism 6. At this time, the leading end of the arm 21 is directed to the diagonally left direction and the hand 23 straight intrudes into the process chamber 5.

From this state, the robot 2 is moved in the right direction of the track 60 and the arm 21 is rotated around the arm spindle 210. In this way, the linear moving mechanism 6 and the arm 21 and the hand 23 are synchronously activated, and thus the hand 23 and the held board 4 are drawn backward not to interfere with the inner walls of the process chamber 5 as illustrated in (b) of FIG. 4.

Then, the hand 23 is rotated around the hand spindle 230, and the leading end of the hand 23 is directed toward the first longitudinal-side wall 110 as illustrated in (c) of FIG. 4.

Then, as illustrated in (d) of FIG. 4, the robot 2 is moved in the left direction of the track 60 and the arm 21 is rotated toward the first longitudinal-side wall 110.

Next, as illustrated in (e) of FIG. 4, the robot 2 is moved in the right direction of the track 60 and the arm 21 is continuously rotated toward the first longitudinal-side wall 110. At the same time, the posture of the hand 23 is controlled while rotating the hand, the hand 23 accesses the storage vessel 3, and the processed board 4 is stored.

Next, carrying operations for making the hand 23 located in the process chamber 5 at the left side of the drawing access the right-side storage vessel 3 diagonally opposite to the process chamber will be explained with reference to FIG. 5.

Operations of the robot 2 in (a) to (c) of FIG. 5 are the same as those of (a) to (c) of FIG. 4 described above.

By driving the linear moving mechanism 6 from the state of (c) of FIG. 5 where the leading end of the hand 23 is directed toward the first longitudinal-side wall 110, the robot 2 is moved in the right direction of the track 60 (see FIG. 1) as illustrated in (d) of FIG. 5.

At this time, the arm 21 is rotated around the arm spindle 210 and the hand 23 is rotated around the hand spindle 230. The arm part 200 is moved in parallel from near the second short-side wall 140 to near the first short-side wall 130 as illustrated in (e) of FIG. 5.

Next, as illustrated in (f) of FIG. 5, the robot 2 is moved in the left direction of the track 60 and the arm 21 is rotated toward the first longitudinal-side wall 110. At the same time, the posture of the hand 23 is controlled while rotating the hand 23, the hand 23 accesses the right-side storage vessel 3, and the processed board 4 is stored.

### ALTERNATIVE EXAMPLES

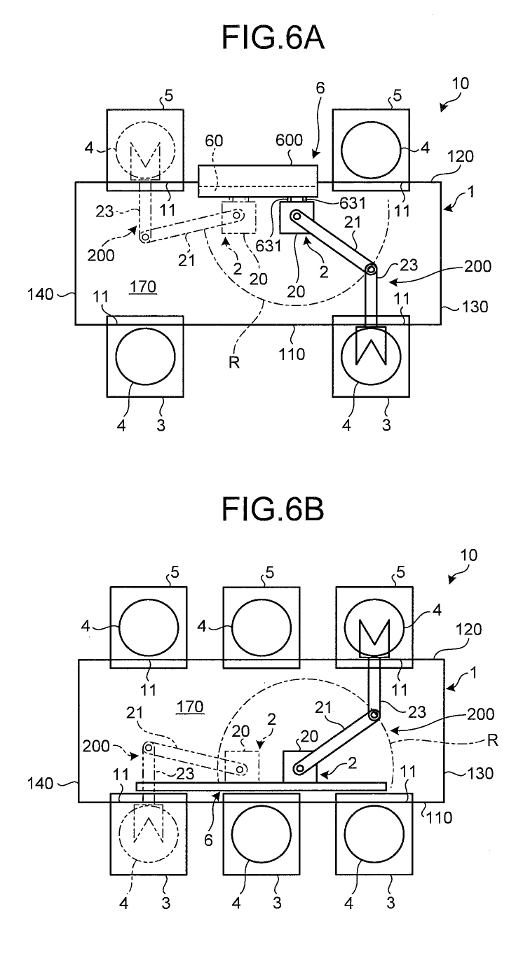

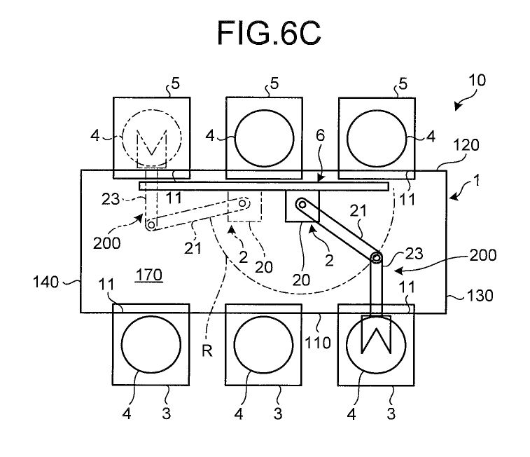

FIGS. 6A to 6C illustrate alternative examples of the carrier device 10. In the alternative examples illustrated in FIGS. 6A to 6C, the same components as those of the carrier device 10 according to the embodiment described above have the same reference numbers and their explanations are omitted.

### First Alternative Example

An alternative example illustrated in FIG. 6A will be explained. In the embodiment described above, it has been explained that the linear moving mechanism 6 is provided in the first longitudinal-side wall 110 of the carrier chamber (see FIGS. 1 and 2). However, in the carrier device 10 illustrated in FIG. 6A, the linear moving mechanism 6 is placed in the second longitudinal-side wall 120. This alternative example also has the same effect as that of the carrier device 10 according to the embodiment.

Furthermore, it has been explained in the embodiment that the linear moving mechanism 6 is placed between the left and right storage vessels 3. However, in the carrier device 10 according to the alternative example, the linear moving mechanism 6 is placed between the left and right process chambers 5 provided in the second longitudinal-side wall 120.

Moreover, depending on the heights of the process chamber 5 and the storage vessel 3 or by appropriately changing these sizes, the linear moving mechanism 6 can be placed to overlap with the process chamber 5 and the storage vessel 3 at substantially the same position as those when being viewed from the top.

### Second Alternative Example

Next, an alternative example illustrated in FIG. 6B will be explained. In the carrier device 10 illustrated in FIG. 6B, the three storage vessels 3 are attached to the first longitudinal-side wall 110 and the substantially-same-size three process chambers 5 are provided in the second longitudinal-side wall 120. In other words, one of the connecting holes 11, to which the storage vessel 3 and the process chamber 5 are attached, is located in the substantial center of the first and second longitudinal-side walls 110 and 120 in its longitudinal direction.

Herein, the linear moving mechanism 6 is provided in the floor wall 160 (see FIG. 2) of the carrier chamber 1. In the case of the linear moving mechanism 6, the ball screw mechanism 61, a linear motor, or the like can be used as a linear actuator. For example, the linear motor is placed near the first longitudinal-side wall 110 in a longitudinal direction, and the robot 2 is moved by the linear motor along with the base 20. This alternative example has the same effect as that of the carrier device 10 according to the embodiment described above.

### Third Alternative Example

In the carrier device 10 illustrated in FIG. 6C, the three storage vessels 3 are attached to the first longitudinal-side wall 110 and the substantially-same-size three process chambers 5 are provided in the second longitudinal-side wall 120.

As illustrated in FIG. 6C, in the present alternative example, the linear moving mechanism 6 is provided near the second longitudinal-side wall 120 of the floor wall 160 (see FIG. 2). In this case, the linear moving mechanism 6 has the same configuration as that of the second alternative example described above.

The carrier device 10 according to the third alternative example has the same effect as that of the carrier device 10 according to the embodiment and alternative examples described above.

Meanwhile, the second and third alternative examples illustrated in FIGS. 6B and 6C have the configuration that the track 60 is comparatively long compared to the linear moving mechanism 6 according to the embodiment and the first alternative example. Therefore, by moving the robot 2 up to an appropriate position, the hand 23 can easily access the central storage vessel 3 and process chamber 5 among the storage vessels 3 and the process chambers 5 that are arranged side-by-side in the longitudinal direction of the first longitudinal-side wall 110 and the second longitudinal-side wall 120.

In the alternative examples illustrated in FIGS. 6B and 6C, the linear moving mechanism 6 (the track 60) is placed to have a length that equally extends left and right by using the middle position of the central storage vessel 3 or the process chamber 5 as a standard. However, it is preferable that the length of the linear moving mechanism 6 satisfies a minimum necessary length condition for the leading end of the hand 23 perpendicular to the track 60 to reach a predetermined position in the connecting hole 11 located at the end among the plurality of connecting holes 11.

Therefore, the linear moving mechanism 6 can be also defined to a minimum necessary length for the leading end of the hand 23 perpendicular to the track 60 to reach the central storage vessel 3 or process chamber 5 and to reach a predetermined position in the connecting hole 11 located at one of the left and right ends. In other words, the linear moving mechanism 6 can be unevenly extended in any direction of the left and right by using the middle position of the central storage vessel 3 or the process chamber 5 as a standard.

In the first and second alternative examples, it has been explained that the linear moving mechanism 6 is provided in the floor wall 160. However, the linear moving mechanism 6 can be attached on any wall surface of the first and second longitudinal-side walls 110 and 120 as explained in the embodiment and alternative examples (see FIGS. 1 to 5).

In this way, the linear moving mechanism 6 may be provided on any wall surface of the first and second longitudinal-side walls 110 and 120 or may be provided in the state where it overlaps with the process chamber 5 or the storage vessel 3. Furthermore, the linear moving mechanism 6 is not be provided on the first and second longitudinal-side walls 110 and 120 but may be provided on the floor wall 160 that is close to any of the first and second longitudinal-side walls 110 and 120.

As described above, the carrier device 10 according to the present embodiment includes a combination of the arm part 200, which includes the single arm 21 that is provided with the hand 23, and the linear moving mechanism 6 that straight moves the arm part 200 along with the base 20 in the longitudinal direction of the carrier chamber 1. Then, the carrier device 10 synchronously activates the arm part 200 and the linear moving mechanism 6. Therefore, it is possible to improve an access speed of the hand 23 to the storage vessel 3 and the process chamber 5 and to improve the precision of an access position while effectively using the board carrying space 170 in the carrier chamber 1.

Meanwhile, the robot 2 of the carrier device 10 according to the present embodiment is a one-arm robot that has the one arm part 200 that includes the arm 21 and the hand 23. However, the robot 2 may be a two-arm robot that has the two arm parts 200 or may be a multi-arm robot that has the three or more arm parts 200. When the robot 2 is a two-arm robot, the robot 2 can take out the board 4 via the predetermined connecting hole 11 by using the one arm part 200 and take in the new board 4 via the connecting hole 11 by using the other arm part 200 to simultaneously perform two work operations.

It has been explained that the robot 2 according to the present embodiment has the single hand 23. However, the robot 2 may have a configuration that a plurality of hands is provided on the leading end of the arm 21 in a multistage manner.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A carrier device comprising:
a carrier chamber that has a substantially rectangular-solid board carrying space surrounded by walls and has a plurality of connecting holes that are provided side-by-side in longitudinal-side walls of peripheral walls to be communicated with an outside;
a robot that is placed near the one longitudinal-side wall in the carrier chamber and of which a bottom end is provided on a base to be rotatable horizontally via an arm spindle and a leading end is provided with an single arm on which a hand that holds a board to be carried in and out via the connecting hole is provided to be rotatable horizontally; and
a linear moving mechanism that has a track along which the robot is linearly moved in a longitudinal direction of the carrier chamber, wherein
the arm of the robot is defined to a length by which the arm does not interfere with the other longitudinal-side wall even if the arm is rotated around the arm spindle, and
the track of the linear moving mechanism has a length by which a leading end of the hand perpendicular to the track reaches a predetermined position in the connecting hole located at an end among the plurality of connecting holes.

2. The carrier device according to claim 1, wherein
at least one of the plurality of connecting holes is located in a substantial center of the longitudinal-side wall in its longitudinal direction, and
the track of the linear moving mechanism has a length by which the leading end of the hand perpendicular to the track reaches a predetermined position in the connecting hole that is located at the substantial center.

3. The carrier device according to claim 1, wherein the track of the linear moving mechanism is defined to a minimum necessary length for the leading end of the hand perpendicular to the track to reach a predetermined position in the connecting hole located at the end among the plurality of connecting holes.

4. The carrier device according to claim 2, wherein the track of the linear moving mechanism is defined to a minimum necessary length for the leading end of the hand perpendicular to the track to reach a predetermined position in the connecting hole located at the end among the plurality of connecting holes.

5. The carrier device according to claim 1, further comprising a control device that performs operation control of the robot including a rotation operation of the arm and operation control of the linear moving mechanism.

6. The carrier device according to claim 2, further comprising a control device that performs operation control of the robot including a rotation operation of the arm and operation control of the linear moving mechanism.

7. The carrier device according to claim 3, further comprising a control device that performs operation control of the robot including a rotation operation of the arm and operation control of the linear moving mechanism.

8. The carrier device according to claim 4, further comprising a control device that performs operation control of the robot including a rotation operation of the arm and operation control of the linear moving mechanism.

9. The carrier device according to claim 5, wherein the control device synchronously activates the linear moving mechanism and at least the arm of the robot.

10. The carrier device according to claim 6, wherein the control device synchronously activates the linear moving mechanism and at least the arm of the robot.

11. The carrier device according to claim 7, wherein the control device synchronously activates the linear moving mechanism and at least the arm of the robot.

12. The carrier device according to claim 8, wherein the control device synchronously activates the linear moving mechanism and at least the arm of the robot.

13. The carrier device according to claim 1, wherein the linear moving mechanism includes a linear actuator that transfers the robot along with the base.

14. The carrier device according to claim 2, wherein the linear moving mechanism includes a linear actuator that transfers the robot along with the base.

15. The carrier device according to claim 3, wherein the linear moving mechanism includes a linear actuator that transfers the robot along with the base.

16. The carrier device according to claim 4, wherein the linear moving mechanism includes a linear actuator that transfers the robot along with the base.

17. The carrier device according to claim 1, wherein the track of the linear moving mechanism is provided in the one longitudinal-side wall.

18. The carrier device according to claim 1, wherein
the linear moving mechanism has a storage frame that moves along the track, and
the robot is placed in the storage frame.
